(19) United States
(12) Patent Application Publication
(10) Pub. No.: US 2015/0062452 A1
(43) Pub. Date: Mar. 5, 2015

(54) TOUCH PANEL

(71) Applicant: TIANJIN FUNAYUANCHUANG TECHNOLOGY CO., LTD., Tianjin (CN)

(72) Inventors: PO-SHENG SHIH, Hsinchu (TW); CHIEN-YUNG CHENG, Hsinchu (TW); CHIH-HAN CHAO, Hsinchu (TW); JIA-SHYONG CHENG, Hsinchu (TW)

(73) Assignee: TIANJIN FUNAYUANCHUANG TECHNOLOGY CO.,LTD., Tianjin (CN)

(21) Appl. No.: 14/200,037

(22) Filed: Mar. 7, 2014

(30) Foreign Application Priority Data
Aug. 30, 2013 (CN) 2013103869118

(51) Int. Cl. G06F 3/044; G06F 3/041; H03K 17/96

(52) U.S. Cl. CPC G06F 3/044; H03K 17/962; G06F 3/0412; H03K 2017/9615; H03K 2217/9607; G06F 2203/04101
USPC 349/12; 200/600

(57) ABSTRACT

A touch panel is disclosed. The touch panel comprises a first electrode plate and a second electrode plate spaced from first electrode plate. The first electrode plate comprises a first conductive layer and a second conductive layer opposite to the first conductive layer. The first conductive layer and the second conductive layer form a two-dimensional coordinate touching module. The second electrode plate comprises a third conductive layer. A distance between the second conductive layer and the third conductive layer is deformable. The second conductive layer and the third conductive layer form a third-dimensional coordinate touching module.

### RELATED APPLICATIONS

This application claims all benefits accruing under 36 U.S.C. §119 from China Patent Application No. 201310386911.8, filed on Aug. 30, 2013 in the China Intellectual Property Office, the disclosure of which is incorporated herein by reference.

This application is related to applications entitled, “METHOD FOR DETECTING TOUCH POINTS OF TOUCH PANEL,” filed ______ (Atty. Docket No. US53378); and entitled, “METHOD FOR DETECTING TOUCH POINTS OF TOUCH PANEL,” filed ______ (Atty. Docket No. US53382).

### BACKGROUND

1. Technical Field

The present disclosure relates to a touch panel, especially a three-dimensional touch panel.

2. Description of Related Art

Touch sensing technology is capable of providing a natural interface between an electronic system and a user, and has found widespread applications in various fields, such as mobile phones, personal digital assistants, automatic teller machines, game machines, medical devices, liquid crystal display devices, and computing devices.

There are different types of touch panels. However, these touch panels can only achieve two-dimensional control, not three-dimensional control.

What is needed, therefore, is to provide a touch panel, which can overcome the above-described shortcomings.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a schematic view of one embodiment of a capacitive touch panel.

FIG. 2 shows a schematic view of different conductive layers of the capacitive touch panel of FIG. 1 when the capacitive touch panel is pressed by a pressure.

FIG. 3 shows a schematic view of a change of an interval of the capacitive touch panel of FIG. 1 when the capacitive touch panel is pressed by a pressure.

FIG. 4 is a flow chart of one embodiment of a method for detecting a touch point by using the capacitive touch panel of FIG. 1.

FIG. 5 shows a schematic view of a capacitance change between the first conductive layer and the second conductive layer of the capacitive touch panel of FIG. 1, when the capacitive touch panel is pressed by a pressure.

FIG. 6 shows a schematic view of a capacitance change between the second conductive layer and the third conductive layer of the capacitive touch panel of FIG. 1, when the capacitive touch panel is pressed by a pressure.

FIG. 7 is a schematic view of another embodiment of a capacitive touch panel.

FIG. 8 is a flow chart of one embodiment of a method for detecting a touch point of the capacitive touch panel of FIG. 7.

FIG. 9 shows a schematic view of a capacitance change between the second conductive layer and the fourth conductive layer of the capacitive touch panel of FIG. 7, when the capacitive touch panel is pressed by a pressure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

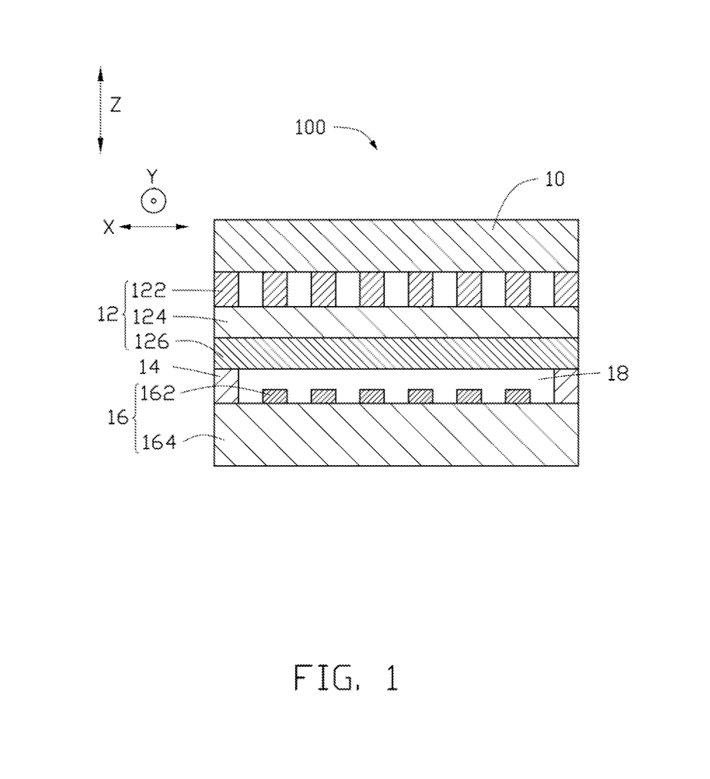

Referring to FIG. 1, according to one embodiment, a capacitive touch panel 100 comprises a first electrode plate 12, a number of supporters 14 and a second electrode plate 16. The first electrode plate 12 and the second electrode plate 16 are spaced from each other by the supporters 14 to form an interval 18. The interval 18 between the first electrode plate 12 and the second electrode plate 16 can be changed when a pressure is applied on the capacitive touch panel 100.

The first electrode plate 12 comprises a first conductive layer 122, a first substrate 124 and a second conductive layer 126. The first conductive layer 122 and the second conductive layer 126 form a two-dimensional coordinate touching module capable of detecting the coordinates along two directions (e.g., X and Y shown in FIG. 1) substantially parallel to a surface of the touch panel 100. The first conductive layer 122 is located on a first surface of the first substrate 124 away from the second electrode plate 16. The first conductive layer 122 comprises a number of first conductive channels. The second conductive layer 126 is located on a second surface of the first substrate 124 adjacent to the second electrode plate 16. The second conductive layer 126 comprises a number of second conductive channels. Each of the first conductive channels is aligned along a first direction. Each of the second conductive channels is aligned along a second direction. The first direction and the second direction cross with each other. A first capacitance can be formed between each of the first conductive channels and each of the second conductive channels. The first capacitance can be used to detect a two-dimensional coordinate (X, Y) of a touch point. In one embodiment, the first direction and the second direction are substantially perpendicular with each other and substantially parallel to Y axis and X axis respectively. The number of the first conductive channels and the second conductive channels can be selected according to a size and a touch-control precision of the capacitive touch panel 100.

The second electrode plate 16 comprises a third conductive layer 162 and a second substrate 164. The third conductive layer 162 is located on a first surface of the second substrate 164 adjacent to the first electrode plate 12. Thus, the third conductive layer 162 and the second conductive layer 126 are spaced from each other by the interval 18. The second conductive layer 126 and the third conductive layer 162 form a third-dimensional coordinate touching module capable of detecting the coordinate along a direction (e.g., Z shown in FIG. 1) substantially perpendicular to the surface of the touch panel 100. The third conductive layer 162 comprises a number of third conductive channels arranged substantially along a third direction. The third direction of the third conductive channels and the second direction of the second conductive channels cross with each other. In one embodiment, the third direction of the third conductive channels is substantially perpendicular to the second direction of the second conductive channels. That is, each of the third conductive channels can also be aligned substantially along the first direction. A second capacitance can be formed between each of the second conductive channels and each of the third conductive channels. The second capacitance can be used to detect a third-dimensional coordinate (Z) of a touch point. The interval 18 between the second conductive channels and the third conductive channels can be changed when a pressure is applied on the capacitive touch panel 100. The number of the third conductive channels can be equal to the number of the first conductive channels.

A material of the first substrate 124 and the second substrate 164 can be a flexible material having a good transparency. The material of the first substrate 124 and the second substrate 164 can be polymethylmethacrylate, polycarbonate, polyethylene terephthalate, polyimide, or cyclic olefin copolymer.

The first conductive layer 122, the second conductive layer 126, and the third conductive layer 162 are all anisotropic impedance layers, and can be formed by ITO, metals, graphene, or a carbon nanotube film. The carbon nanotube film comprises a number of carbon nanotubes arranged substantially along a same direction, and joined end to end substantially along the arranged direction. The carbon nanotubes of the carbon nanotube film are joined end to end substantially along the arranged direction to form a number of conductive channels substantially along the arranged direction. The carbon nanotube film has a minimum impedance along the arranged direction of the carbon nanotubes and a maximum impedance along the direction substantially perpendicular to the arranged direction of the carbon nanotubes, thus having anisotropic impedance. In one embodiment, the first conductive layer 122, the second conductive layer 126, and the third conductive layer 162 are formed by a number of ITO conductive strips.

A material of the supporters 14 can be electric insulative materials.

A gas, an electric insulative fluid, or an elastic electric insulative solid can be filled into the interval 18. The electric insulative fluid and the elastic electric insulative solid can be transparent or translucent. In one embodiment, the capacitive touch panel 100 does not include supporter 14 therein because the first electrode plate 12 and the second electrode plate 16 are spaced from each other by the electric insulative solid.

In one embodiment, the capacitive touch panel 100 further comprises a transparent protective film 10 to protect the first electrode plate 12. A material of the transparent protective film 10 can be silicon nitride, silicon oxide, benzocyclobutene, polyester, or acrylic resin.

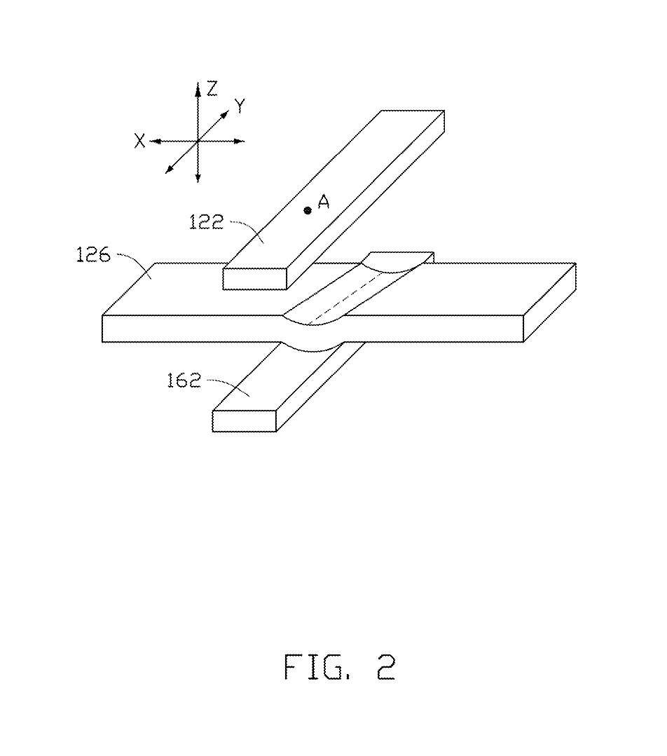

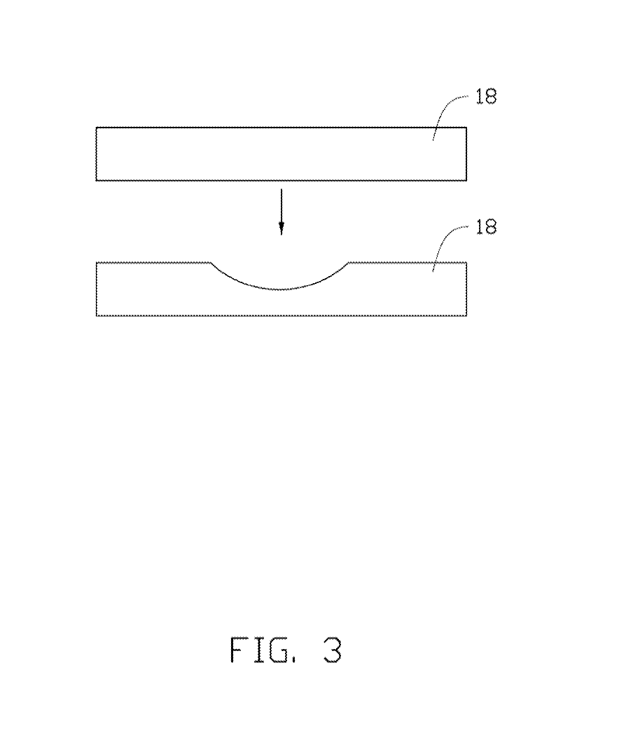

Referring to FIG. 2, when a touch point A is pressed by a user, the value of the first capacitance between the first conductive channels and the second conductive channels can be changed. Thus, the two-dimensional coordinate (X, Y) of the touch point A can be achieved according to a capacitance change of the first capacitance. Referring to FIG. 3, with the decrease of the interval 18 between the second conductive channels and the third conductive channels, the value of the second capacitance increases. Thus, the third-dimensional coordinate (Z) of the touch point A can be achieved according to a capacitance change of the second capacitance.

The capacitive touch panel 100 can further include a display module (not shown). The display module can be located on a second surface of the second substrate 164 opposite to the first surface of the second substrate 164. In one embodiment, a thickness of the capacitive touch panel 100 is decreased because the display module and the second electrode plate 16 share the same second substrate 164.

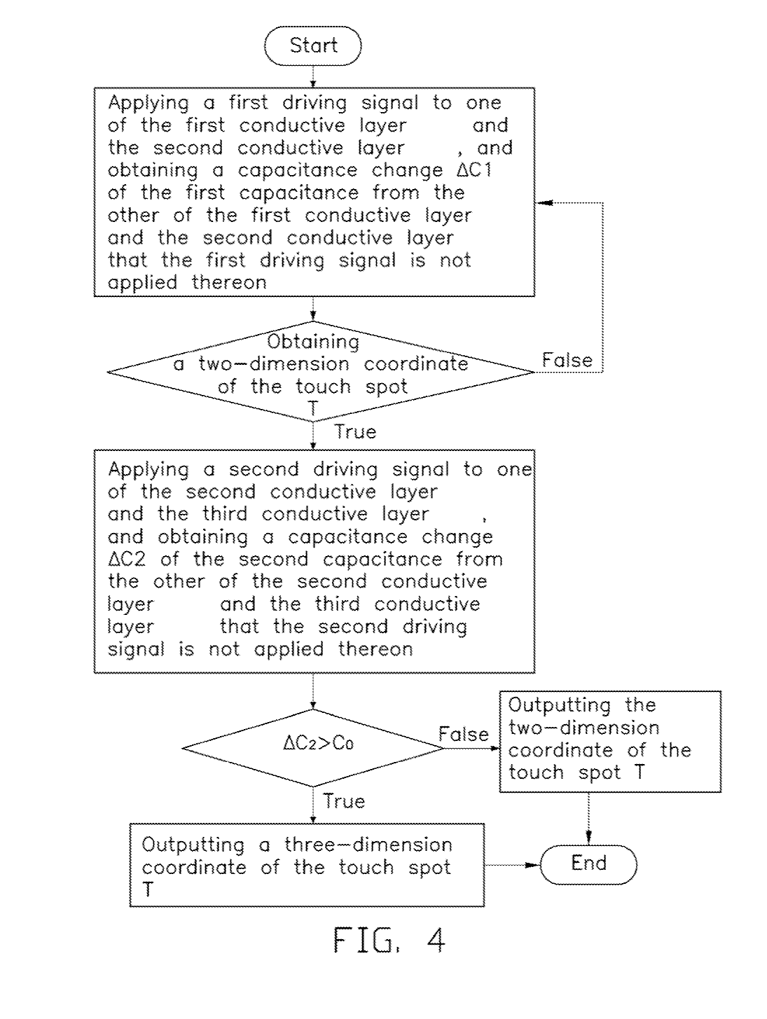

Referring to FIG. 4, one embodiment of a method for detecting a touch point T of the capacitive touch panel 100 comprises:

S10, applying a first driving signal to one of the first conductive layer 122 and the second conductive layer 126, and obtaining a capacitance change ΔC₁ of the first capacitance from the other of the first conductive layer 122 and the second conductive layer 126 that the first driving signal is not applied thereon;

S11, determining a two-dimensional coordinate (X, Y) of the touch point T according to the capacitance change ΔC₁;

S12, applying a second driving signal to one of the second conductive layer 126 and the third conductive layer 162, and obtaining a capacitance change ΔC₂ of the second capacitance from the other of the second conductive layer 126 and the third conductive layer 162 that the second driving signal is not applied thereon;

S13, comparing the ΔC₂ with a threshold value C₀; if ΔC₂>C₀, outputting a three-dimensional coordinate (X, Y, Z) of the touch point T; if ΔC₂≦C₀, outputting the two-dimensional coordinate (X, Y) of the touch point T.

In step S10, when the first driving signal is applied to one of the first conductive layer 122 and the second conductive layer 126, the third conductive layer 162 can be connected to ground. When the first driving signal is applied to the first conductive layer 122, the capacitance change ΔC₁ can be obtained by scanning the second conductive layer 126. When the first driving signal is applied to the second conductive layer 126, the capacitance change ΔC₁ can be obtained by scanning the first conductive layer 122. In one embodiment, the first driving signal is applied to the second conductive layer 126, and the capacitance change ΔC₁ is obtained by scanning the first conductive layer 122. Thus a noise between the first conductive layer 122 and second conductive layer 126 can be reduced.

The first driving signal can be applied to the first conductive channels of the first conductive layer 122 one by one or at the same time. When the first driving signal is applied to the first conductive channels one by one, the other first conductive channels without the first driving signal applied thereon can be connected to ground or floating.

The first driving signal can also be applied to the second conductive channels of the second conductive layer 126 one by one or at the same time. When the first driving signal is applied to the second conductive channels one by one, the other second conductive channels without the first driving signal applied thereon can also be connected to ground or floating. In one embodiment, the first driving signal is applied to the second conductive channels one by one, and the other second conductive channels without the first driving signal applied thereon is connected to ground.

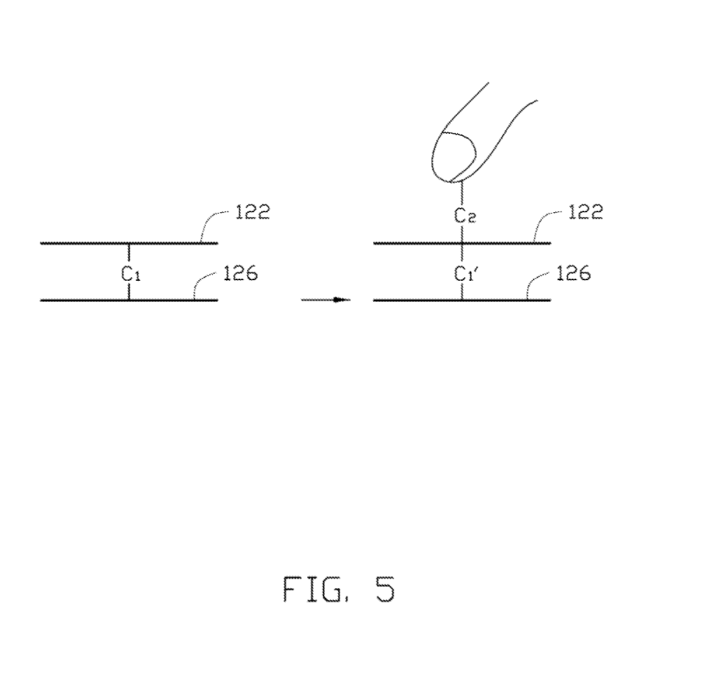

In step S11, referring to FIG. 5, before touching the capacitive touch panel 100, the first capacitance between the first conductive layer 122 and the second conductive layer 126 is C₁. During the touching process, a coupled capacitance C₂ between a finger and the first conductive layer 122 can be formed. The first capacitance between the first conductive layer 122 and the second conductive layer 126 can be affected by the coupled capacitance C₂, and be changed to C₁′. The capacitance change ΔC₁ and the first capacitance C₁ and C₁′ satisfy a formula: ΔC₁=C₁′−C₁. The two-dimensional coordinate (X, Y) of the touch point T can be determined according to the capacitance change ΔC₁.

In step S12, the first conductive layer 122 can be connected to ground.

The capacitance change ΔC₂ of the second capacitance can be obtained by a mutual sensing method. For example, when the second driving signal is applied to the second conductive layer 126, the capacitance change ΔC₂ of the second capacitance can be obtained by scanning the third conductive layer 162; or when the second driving signal is applied to the third conductive layer 162, the capacitance change ΔC₂ of the second capacitance can be obtained by scanning the second conductive layer 126.

The second driving signal can be applied to all of the second conductive channels or the specific second conductive channels having the touch points T applied thereon one by one or at the same time. In one embodiment, a time for applying the second driving signal can be reduced because the second driving signal is applied only to the second conductive channels having the touch point T applied thereon. When the second driving signal is applied to the second conductive channels one by one, the other second conductive channels without the second driving signal applied thereon can be connected to ground or floating. The second driving signal can also be applied to all the third conductive channels of the third conductive layer 162 or the specific third conductive channels having the touch point T applied thereon one by one or at the same time. In another embodiment, the second driving signal is applied to the third conductive channels having the touch point T applied thereon one by one. When the second driving signal is applied to the third conductive channels one by one, the other third conductive channels without the second driving signal applied thereon can be connected to ground or floating.

When the second driving signal is applied to the second conductive channels, the capacitance change ΔC₂ can be obtained by scanning all of the third conductive channels or the specific third conductive channels having the touch points T applied thereon one by one or at the same time. In one embodiment, a period time of scanning the third conductive channels can be reduced because the capacitance change ΔC₂ is obtained only by scanning the third conductive channels having the touch points T applied thereon. When the second driving signal is applied to the third conductive channels, the capacitance change ΔC₂ can be obtained by scanning all of the second conductive channels or the specific second conductive channels having the touch points T applied thereon one by one or at the same time. In another embodiment, the capacitance change ΔC₂ is obtained by scanning the second conductive channels having the touch points T applied thereon.

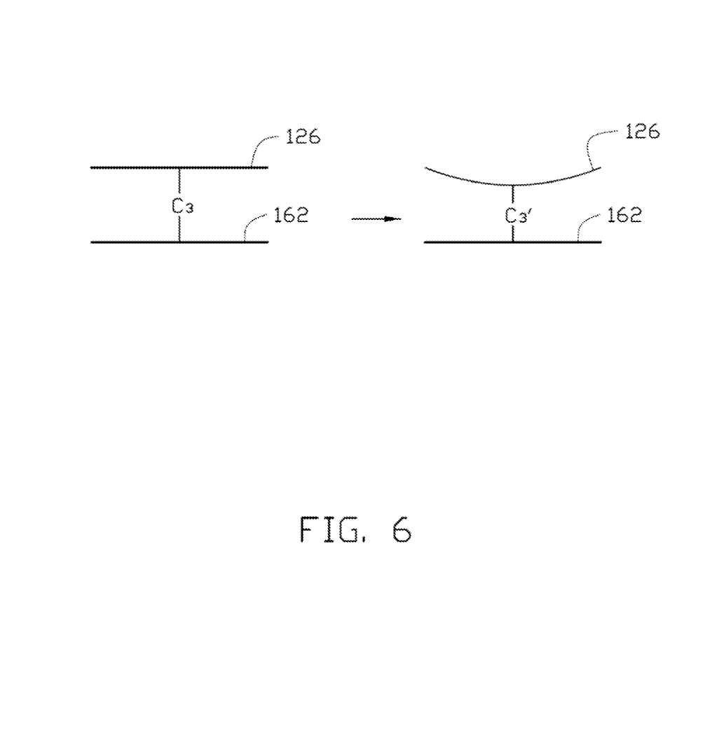

In step S13, the threshold value C₀ can be determined according to a precision of the capacitive touch panel 100, and can be greater than zero. Referring to FIG. 6, before touching, the second capacitance between the second conductive layer 126 and the third conductive layer 162 is C₃. During the touching process, the second capacitance between the second conductive layer 126 and the third conductive layer 162 can be changed to C₃′. The capacitance change ΔC₂ and the second capacitance C₃ and C₃′ satisfy a formula: ΔC₂=C₃′−C₃. If ΔC₂≦C₀, only the two-dimensional coordinate (X, Y) of the touch point T obtained in step S11 is outputted because the interval 18 between the second conductive layer 126 and the third conductive layer 162 is deemed to be unchanged. If ΔC₂>C₀, the third-dimensional coordinate (Z) of the touch point T together with the two-dimensional coordinate (X, Y) of the touch point T obtained in step S11 are outputted because the interval 18 between the second conductive layer 126 and the third conductive layer 162 is deemed to decrease.

A pressure of the touch point T can be defined by the second capacitance C₃ and C₃′. For example, when C₃′=C₃, the pressure of the touch point T can be defined as zero Newton (N); when C₃′=1.1×C₃, the pressure of the touch point T can be defined as 0.1 N; when C₃′=1.2×C₃, the pressure of the touch point T can be defined as 0.2 N, and so on. Furthermore, a second two-dimensional coordinate (X, Y) of the touch point T can also be obtained according to the capacitance change ΔC₂, and be verified with the two-dimensional coordinate (X, Y) obtained according to the capacitance change ΔC₁. Thus, the touch-control precision of the two-dimensional coordinate (X, Y) of the capacitive touch panel 100 can be further improved.

In some embodiments, when the capacitance change ΔC₂ reaches different predetermined values, such as 0.1×C₃, 0.2×C₃, 0.3×C₃, and 0.4×C₃, a different third-dimensional coordinate (Z) of the touch point T can be obtained. Thus, a touch-control precision of the third-dimensional coordinate (Z) of the capacitive touch panel 100 can be improved.

The capacitive touch panel 100 of the present embodiment has the following advantages. First, the pressure of the touch point can be detected by the second electrode plate 16, thus the three-dimensional coordinate of the touch point can be obtained. Second, the two-dimensional coordinate and the third-dimensional coordinate of the touch point is obtained in different steps, thus preventing the two-dimensional coordinate and the third-dimensional coordinate of the touch point from influencing each other. Third, the number of the third conductive channels is equal to the number of the first conductive channels. Thus, different third-dimensional coordinates of different touch points can be obtained at the same time.

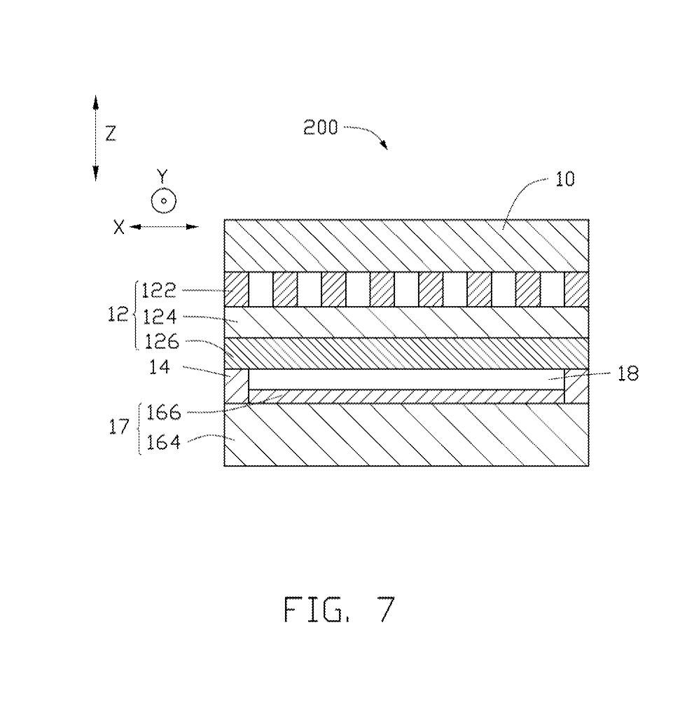

Referring to FIG. 7, according to another embodiment, a capacitive touch panel 200 comprises a first electrode plate 12, a number of supporters 14, and a second electrode plate 17. The second electrode plate 17 is basically the same as the second electrode plate 16, except that the second electrode plate 17 comprises a successive fourth conductive layer 166 having isotropic impedance. That is, the fourth conductive layer 166 has a substantially uniform impedance along different directions. The second conductive layer 126 and the fourth conductive layer 166 form a third-dimensional coordinate touching module capable of detecting the coordinate along a direction (e.g., Z shown in FIG. 7) substantially perpendicular to the surface of the touch panel 200. The fourth conductive layer 166 can be a transparent structure or a translucent structure. The fourth conductive layer 166 can be a successive ITO layer, a successive metal layer, a successive graphene layer, or a successive carbon nanotube layer having a number of carbon nanotubes uniformly dispersed therein.

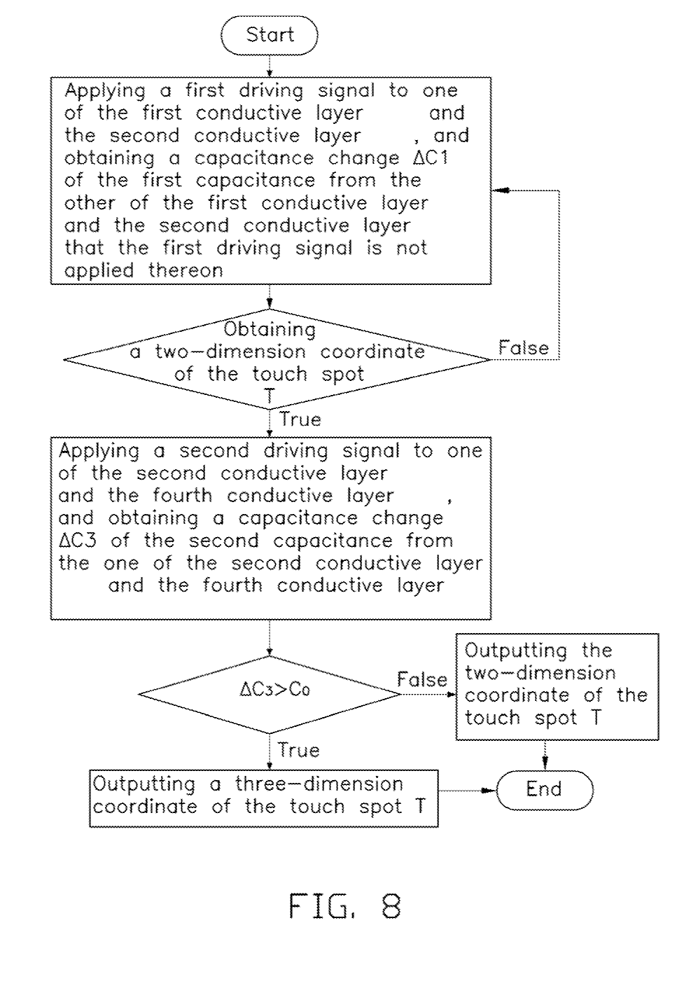

Referring to FIG. 8, another embodiment of a method for detecting the touch point T of the capacitive touch panel 200 comprises:

S20, applying a first driving signal to one of the first conductive layer 122 and the second conductive layer 126, and obtaining a capacitance change ΔC₁ of the first capacitance from the other of the first conductive layer 122 and the second conductive layer 126 that the first driving signal is not applied thereon;

S21, determining a two-dimensional coordinate (X, Y) of the touch point T according to the capacitance change ΔC₁;

S22, applying a second driving signal to one of the second conductive layer 126 and the fourth conductive layer 166, and obtaining a capacitance change ΔC₃ of the second capacitance from the one of the second conductive layer 126 and the fourth conductive layer 166;

S23, comparing ΔC₃ with a threshold value C₀; if ΔC₃>C₀, outputting a three-dimensional coordinate (X, Y) of the touch point T; if ΔC₃≦C₀, outputting the two-dimensional coordinate (X, Y, Z) of the touch point T.

Steps S20 and S21 are the same as the steps S10 and S11 respectively.

In step S22, the capacitance change ΔC₃ can be obtained by a self-sensing method or the mutual-sensing method. In the self-sensing method, the second driving signal is applied to the second conductive layer 126 or the fourth conductive layer 166, and the capacitance change ΔC₃ is obtained by scanning the second conductive layer 126 or the fourth conductive layer 166 with the second driving signal applied thereon at the same time.

In one embodiment, the second driving signal is applied to the second conductive layer 126, and the capacitance change ΔC₃ is obtained by scanning the second conductive layer 126 at the same time. At this time, the first conductive layer 122 and the fourth conductive layer 166 can be connected to ground or floating. Specifically, the second driving signal can be applied to a first end of the second conductive channels of the second conductive layer 126, and the capacitance change ΔC₃ can be obtained by scanning the first end or a second end opposite to the first end of the second conductive channels at the same time. In one embodiment, the second driving signal is applied to the first end of the specific second conductive channels having the touch point T applied thereon, and the capacitance change ΔC₃ is obtained by scanning the second end opposite to the first end of the second conductive channels at the same time. Thus, a period time of step S22 can be reduced.

In another embodiment, a single second driving signal is applied to the fourth conductive layer 166, and the capacitance change ΔC₃ is obtained by scanning the fourth conductive layer 166 at the same time. This is because the fourth conductive layer 166 is a successive conductive layer having a substantially uniform impedance along different directions. At this time, the first conductive layer 122 and the second conductive layer 126 can be connected to ground or floating.

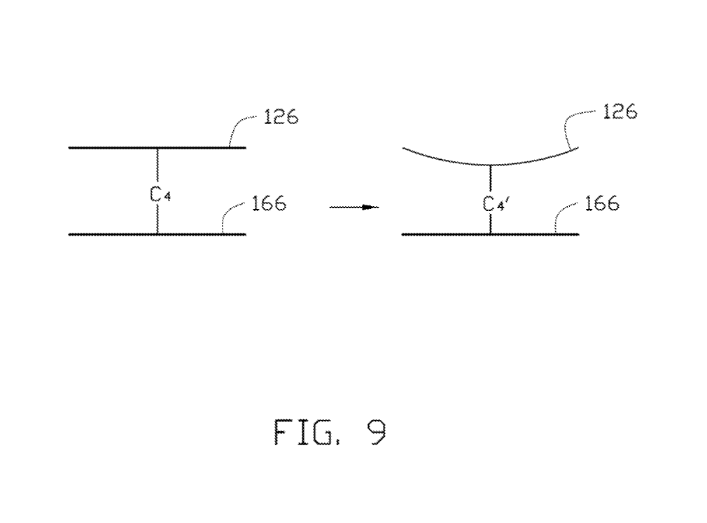

In step S23, the threshold value C₀ can be determined according to a precision of the capacitive touch panel 200, and can be greater than zero. Referring to FIG. 9, before touching, the second capacitance between the second conductive layer 126 and the fourth conductive layer 166 is C₄. During touching, the second capacitance between the second conductive layer 126 and the fourth conductive layer 166 can be changed to C₄′. The capacitance change ΔC₃ and the second capacitance C₄ and C₄′ can satisfy a formula: ΔC₃=C₄′−C₄. If ΔC₃≦C₀, only the two-dimensional coordinate (X, Y) of the touch point T obtained in step S21 is outputted because the interval 18 between the second conductive layer 126 and fourth conductive layer 166 is deemed to be unchanged. If ΔC₂>C₀, the third-dimensional coordinate (Z) of the touch point T together with the two-dimensional coordinate (X, Y) of the touch point T obtained in step S21 are outputted because the interval 18 between the second conductive layer 126 and the fourth conductive layer 166 is deemed to decrease.

A pressure of the touch point T can be defined by the second capacitance C₄ and C₄′. For example, when C₄′=C₄, the pressure of the touch point T can be defined as zero N; when C₄′=1.1×C₄, the pressure of the touch point T can be defined as 0.1 N; when C₄′=1.2×C₄, the pressure of the touch point T can be defined as 0.2 N, and so on.

In some embodiments, when the capacitance change ΔC₃ reaches different predetermined values, such as 0.1×C₄, 0.2×C₄, 0.3×C₄, and 0.4×C₄, different third-dimensional coordinates of the touch point T can be obtained. Thus, a touch-control precision of the third-dimensional coordinate (X, Y, Z) of the capacitive touch panel 200 can be improved.

Finally, it is to be understood that the above-described embodiments are intended to illustrate rather than limit the present disclosure. Variations may be made to the embodiments without departing from the spirit of the disclosure as claimed. Elements associated with any of the above embodiments are envisioned to be associated with any other embodiments. The above-described embodiments illustrate the scope of the disclosure but do not restrict the scope of the disclosure.

Depending on the embodiment, certain of the steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

What is claimed is:

1. A touch panel comprising:
a first electrode plate comprising a first conductive layer, a second conductive layer and a first substrate, wherein the first conductive layer is located at a first surface of the first substrate and comprises a plurality of first conductive channels aligned substantially along a first direction; the second conductive layer is located a second surface of the first substrate and comprises a plurality of second conductive channels aligned substantially along a second direction being crossed with the first direction;
a second electrode plate comprising a second substrate and a third conductive layer located on a third surface of the second substrate adjacent to the second conductive layer, wherein the third conductive layer comprises a plurality of third conductive channels aligned substantially along a third direction being crossed with the second direction;
the second electrode plate being spaced from first electrode plate, and a distance between the first electrode plate and the second electrode plate being deformable.

2. The touch panel as claimed in claim 1, wherein the first direction is substantially perpendicular to the second direction.

3. The touch panel as claimed in claim 2, wherein the third direction is substantially perpendicular to the second direction.

4. The touch panel as claimed in claim 1, wherein the third direction is substantially parallel to the first direction.

5. The touch panel as claimed in claim 1, further comprising a plurality of supporters located between the first electrode plate and the second electrode plate, and an interval is defined between the first electrode plate and the second electrode plate.

6. The touch panel as claimed in claim 5, wherein the interval is filled with a gas, an electric insulative fluid, or an elastic electric insulative solid.

7. The touch panel as claimed in claim 1, further comprising an elastic electric insulative solid located between the first electrode plate and the second electrode plate.

8. The touch panel as claimed in claim 1, further comprising a display module located on a fourth surface of the second substrate opposite to the third surface of the second substrate, and the display module shares the same second substrate with the second electrode plate.

9. A touch panel comprising:
a first electrode plate comprising a first conductive layer, a second conductive layer, and a first substrate, wherein the first conductive layer is located at a first surface of the first substrate and comprises a plurality of first conductive channels aligned along a first direction; the second conductive layer is located at a second surface of the first substrate and comprises a plurality of second conductive channels aligned along a second direction being crossed with the first direction;
a second electrode plate comprising a second substrate and a third conductive layer located on a third surface of the second substrate adjacent to the second conductive layer, wherein the third conductive layer has isotropic impedance;
the second electrode plate being spaced from first electrode plate, and a distance between the first electrode plate and the second electrode plate being deformable.

10. The touch panel as claimed in claim 9, wherein the first direction is substantially perpendicular to the second direction.

11. The touch panel as claimed in claim 9, wherein the third conductive layer is a successive ITO layer, a successive metal layer, a successive graphene layer or a successive carbon nanotube layer having a plurality of carbon nanotubes uniformly dispersed therein.

12. The touch panel as claimed in claim 9, further comprising a plurality of supporters located between the first electrode plate and the second electrode plate, and an interval is defined between the first electrode plate and the second electrode plate.

13. The touch panel as claimed in claim 12, wherein the interval is filled with a gas, an electric insulative fluid or an elastic electric insulative solid.

14. The touch panel as claimed in claim 9, further comprising an elastic electric insulative solid located between the first electrode plate and the second electrode plate.

15. The touch panel as claimed in claim 9, further comprising a display module located on a fourth surface of the second substrate opposite to the third surface of the second substrate, and the display module shares the same second substrate with the second electrode plate.

16. A touch panel comprising:
a first electrode plate comprising a first conductive layer, a second conductive layer and a first substrate, wherein the first conductive layer is located at a first surface of the first substrate; the second conductive layer is located at a second surface of the first substrate, the first conductive layer and the second conductive layer form a two-dimensional coordinate touching module;
a second electrode plate comprising a second substrate and a third conductive layer located on a third surface of the second substrate adjacent to the second conductive layer, wherein the second conductive layer and the third conductive layer form a third-dimensional coordinate touching module;
the second electrode plate being spaced from first electrode plate, and a distance between the first electrode plate and the second electrode plate being deformable.

17. The touch panel as claimed in claim 16, further comprising an elastic electric insulative solid located between the first electrode plate and the second electrode plate.

18. The touch panel as claimed in claim 16, further comprising a display module located on a fourth surface of the second substrate opposite to the third surface of the second substrate, and the display module shares the same second substrate with the second electrode plate.

19. The touch panel as claimed in claim 16, wherein the third conductive layer comprises a plurality of third conductive channels aligned substantially along a same direction.

20. The touch panel as claimed in claim 16, wherein the third conductive layer is a successive ITO layer, a successive metal layer, a successive graphene layer, or a successive carbon nanotube layer having a plurality of carbon nanotubes uniformly dispersed therein.
